(19) United States
(12) Patent Application Publication
(10) Pub. No.: US 2003/0140853 A1
(43) Pub. Date: Jul. 31, 2003

(54) Substrate processing apparatus

(75) Inventors: Tetsuya Wada, Tokyo (JP); Harunobu Sakuma, Tokyo (JP); Toshio Ando, Tokyo (JP); Tsuyoshi Tamaru, Tokyo (JP)

Correspondence Address: BACON & THOMAS, PLLC, 625 SLATERS LANE, FOURTH FLOOR, ALEXANDRIA, VA, 22314

(73) Assignee: Hitachi Kokusai Electric Inc., Tokyo (JP)

(21) Appl. No.: 10/347,360

(22) Filed: Jan. 21, 2003

(30) Foreign Application Priority Data
Jan. 21, 2002 (JP) 2002-011135

(51) Int. Cl. C23C 16/00

(52) U.S. Cl. 118/715; 427/248.1; 118/724

(57) ABSTRACT

A substrate processing apparatus includes a reaction chamber, a protection cover, a first heater, a second heater, and a gas supply pipe. The reaction chamber has a wall side and the protection cover covers an inner surface of the wall side. The first heater is interposed between the wall side and the protection cover and serves to heat the protection cover. The second heater is positioned in the reaction chamber and serves to heat a substrate transported in the reaction chamber. The gas supply pipe communicates with the reaction chamber and serves to supply material gas on the substrate.

### FIELD OF THE INVENTION

The present invention relates to a substrate processing apparatus; and, more particularly, to a chemical vapor deposition (CVD) apparatus for forming a ruthenium (Ru) layer on a semiconductor wafer.

### BACKGROUND OF THE INVENTION

To form a ruthenium (Ru) layer on a semiconductor wafer, a vaporized ruthenium-containing compound such as Ru(EtCp)₂(Ru(C₅H₄C₂H₅)₂) in the form of a material gas is supplied on a surface of the semiconductor wafer in a reaction chamber of a metalorganic chemical vapor deposition (MOCVD) apparatus. FIG. 5 shows a vapor pressure characteristic curve of Ru(EtCp)₂.

While the material gas is supplied on the wafer in the reaction chamber, a low temperature of an inner wall of the reaction chamber may make the material gas condense thereon, thereby contaminating the inner wall. Accordingly, the temperature of the inner wall of the reaction chamber is usually maintained higher than a predetermined minimum value to prevent the condensation of the material gas. On the other hand, a very high temperature of the inner wall may cause formation of a ruthenium layer on portions of the inner wall, thereby wasting the costly Ru(EtCp)₂. The ruthenium layer formed on the inner wall causes another problem in that thermal properties, e.g., emissivity, of the inner wall are changed, thereby altering a thermal environment in the reaction chamber unpredictably. Accordingly, the temperature of the inner wall of the reaction chamber should be kept below a predetermined upper limit. By taking the aforementioned low and high limits into account an optimum temperature of the inner wall is usually determined to be about 150° C. at a pressure of tens to hundreds of Pa in the reaction chamber during the process of forming the ruthenium layer on the wafer.

Such a substrate processing apparatus therefore normally employs a heater to maintain the optimum temperature of the inner wall of the reaction chamber. For example, Japanese Patent Laid-Open Publication No. 2000-235886 teaches a conventional substrate processing apparatus employing a bar-shaped cartridge heater mounted inside an inner wall part at each corner of a reaction chamber.

The aforementioned Japanese Patent is, however, problematical in that the cartridge heater is difficult to repair or replace with new one because it is embedded in the inner wall. Further, heat may be concentrated on certain portions of the inner wall part where the heaters reside. In that case, the surface temperature of such portions of the inner wall part may rise above an upper limit, resulting in a layer formation thereat. The layer formed on the inner wall should be removed by a cleaning process. If the layer cannot be removed therefrom even after the cleaning process, the contaminated portions of the inner wall should be replaced with new ones, thereby increasing the maintenance cost. Furthermore, it is very difficult to uniformly control the temperature of the whole surface of the inner wall because the bar-shaped cartridge heaters are positioned only at the corner portions of the inner wall of the reaction chamber.

### SUMMARY OF THE INVENTION

It is, therefore, a primary object of the present invention to provide a substrate processing apparatus that can be maintained at low cost and can easily control the temperature of a gas-contacting surface of a reaction chamber.

In accordance with one aspect of the invention, there is provided a substrate processing apparatus, which includes: a reaction chamber including a sidewall; a protection cover facing an inner surface of the sidewall of the reaction chamber; a first heater, interposed between the sidewall of the reaction chamber and the protection cover, for heating the protection cover; a second heater positioned in the reaction chamber for heating the substrate; and a gas supplying member communicating with the reaction chamber for supplying a material gas on the substrate.

In accordance with another aspect of the invention, there is provided a method for processing a substrate using a substrate processing apparatus, which includes a) a reaction chamber having a sidewall, b) a protection cover facing an inner surface of the sidewall of the reaction chamber, c) a first heater, interposed between the sidewall of the reaction chamber and the protection cover, for heating the protection cover, d) a second heater positioned in the reaction chamber for heating the substrate, and e) a gas supplying member communicating with the reaction chamber for supplying a material gas on the substrate, the method including the steps of: loading the substrate into the reaction chamber; heating the substrate by using the second heater while the protection cover is heated by using the first heater; supplying the material gas on the substrate by using the gas supplying member to thereby make the substrate processed; and unloading the processed substrate out of the reaction chamber.

### BRIEF DESCRIPTION OF THE DRAWINGS

The above and other objects and features of the present invention will become apparent from the following description of the preferred embodiment given in conjunction with the accompanying drawings, in which:

FIG. 1 shows a cross-sectional view of an MOCVD apparatus in accordance with the preferred embodiment of the present invention;

FIG. 2 provides an expanded cross-sectional view of a part of the MOCVD apparatus in FIG. 1;

FIG. 3 is a cross-sectional view illustrating an operation of the MOCVD apparatus in FIGS. 1 and 2;

FIG. 4 depicts temperature measurement points “a” to “p” in the MOCVD apparatus in FIG. 2; and

FIG. 5 gives a vapor pressure curve of Ru(EtCp)₂.

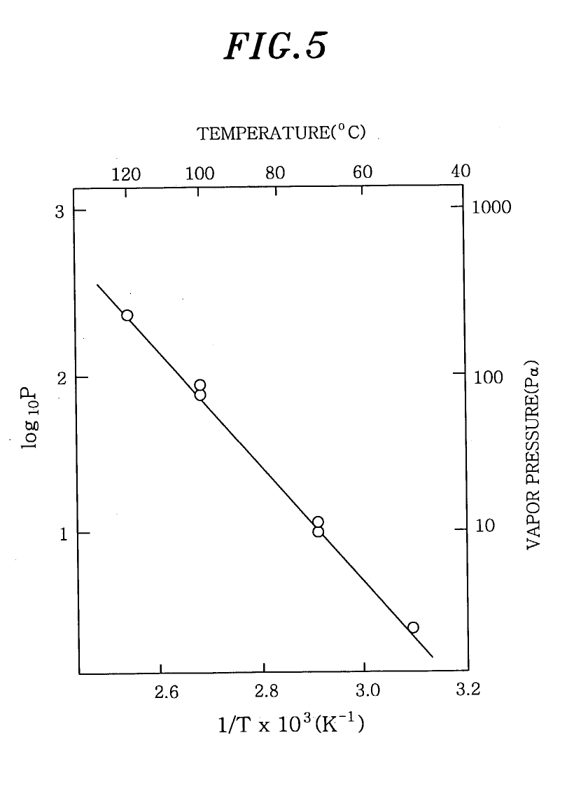

### DETAILED DESCRIPTION OF THE PREFERRED EMBODIMENT

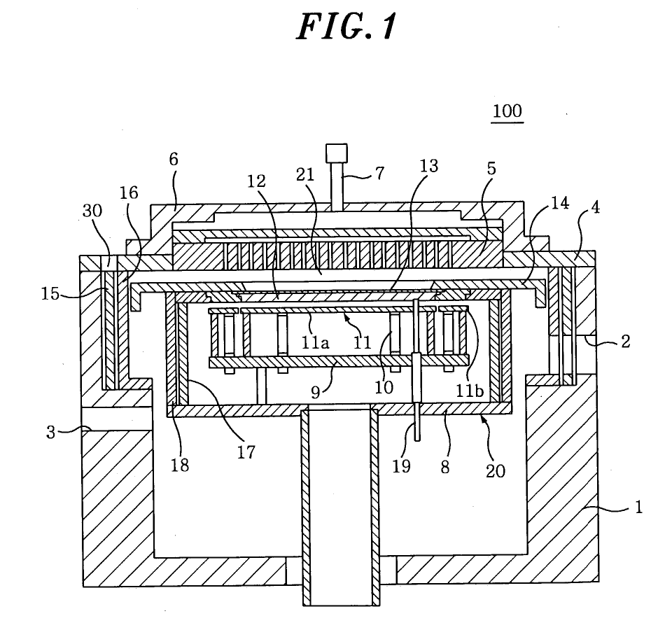

Referring now to FIGS. 1 to 4, a substrate processing apparatus 100 in accordance with the preferred embodiment of the present invention will be described in detail. Like reference numerals represent like parts in the drawings.

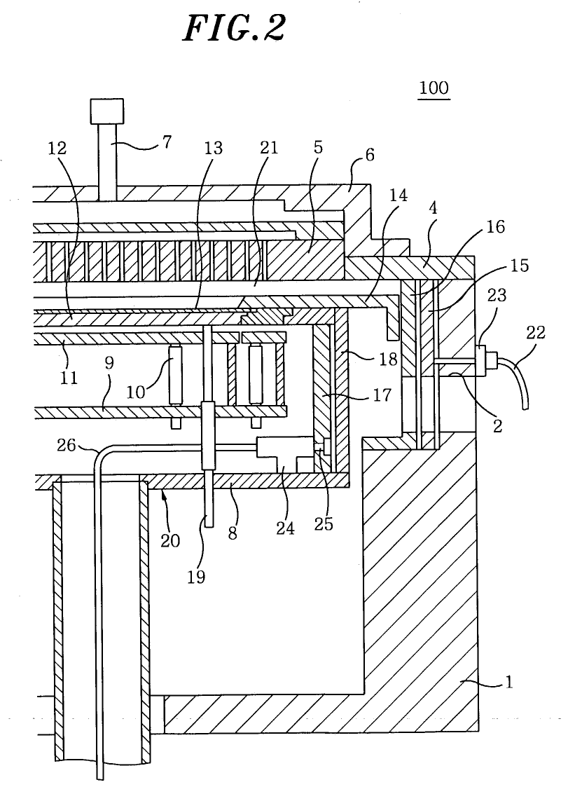

FIG. 1 illustrates a schematic cross-sectional view of the substrate processing apparatus 100 in accordance with the preferred embodiment of the present invention and FIG. 2 provides a detailed expanded view showing a part thereof. The substrate processing apparatus 100 includes a furnace body 1, a supporting plate 4, a shower plate 5, a top cover 6, and a heater unit 20. The furnace body 1 is provided with a gas exhaust outlet 2. The supporting plate 4 is mounted on an upper portion of the furnace body 1 and serves to support the shower plate 5 having a multiplicity of through holes. The top cover 6 provided with a gas supply pipe 7 is formed on the supporting plate 4, wherein the gas supply pipe 7 communicates with space interposed between the shower plate 5 and the top cover 6. The heater unit 20, positioned in the furnace body 1, is moved in a vertical direction by an elevator (not shown).

The heater unit 20 has a supporting structure 8, a base 9, a plate heater 11, and a susceptor 12, wherein the base 9 is mounted over the supporting structure 8; the plate heater 11 is mounted on the base 9 via heater electrodes 10; and the susceptor 12 is positioned over the plate heater 11. The plate heater 11 has a disk-shaped inner heater 11a and a ring-shaped outer heater 11b surrounding the inner heater 11a. A wafer or a semiconductor substrate 13 is loaded on the susceptor 12 and a cover plate 14 is located thereover.

A pin 19 is further provided for the heater unit 20, which passes through the supporting structure 8, the base 9, and the plate heater 11. Specifically, the pin 19 is formed of shape having two diameters, a first diameter at both end portions thereof and a second diameter at a middle portion thereof, wherein the second diameter is greater than the first diameter. The middle portion of the pin 19 can smoothly slide through the base 9 while an upper and a lower end portion thereof can smoothly slide through the plate heater 11 and the supporting structure 8, respectively. The greater diameter prevents the middle portion of the pin 19 from moving beyond the supporting structure 8 and the plate heater 11.

The furnace body 1 forms therein a reaction chamber 21 where the wafer 13 is processed. The wafer 13 can be transported into or out of the reaction chamber 21 via a transporting port 3 provided in the furnace body 1. Further, a first cylindrical heater 15 is installed in the reaction chamber 21, and more specifically, on an inwardly protruded wall portion of the furnace body 1. To cover an inner surface of the sidewall portion of the first cylindrical heater 15, a first cylindrical cover 16, or a first protection cover, made of a ceramic substance such as quartz and alumina is installed on the inwardly protruded wall portion of the furnace body 1. A first feeder line 22 for supplying power to the first cylindrical heater 15 is provided through the furnace body 1 and a sealing part 23 is employed to seal the furnace body 1 at the exit of the first feeder line 22.

The heater unit 20 further has a second cylindrical heater 17, a second cylindrical cover 18, and a feeder part 24, which are positioned on the supporting structure 8. The second cylindrical heater 17 and the feeder part 24 are joined together via a bolt 25. The second cylindrical cover 18, or a second protection cover, made of a ceramic substance such as quartz and alumina surrounds the second cylindrical heater 17 for the purpose of protection and constitutes an outer wall of the heater unit 20. A second feeder line 26 for supplying power to the second cylindrical heater 17 is electrically connected to the second cylindrical heater 17 via the feeder part 24, wherein the second feeder line 26 exits through a lower portion of the furnace body 1. Another sealing part (not shown) is employed to seal the lower portion of the furnace body 1 at the exit of the second feeder line 26.

The first cylindrical heater 15 is fabricated by forming a heating resistor on an inner wall of a cylindrical ceramic structure and performing an insulation treatment, e.g., glass coating thereon. The second cylindrical heater 17 is fabricated by forming a heating resistor on an outer wall of a cylindrical ceramic structure and performing an insulation treatment, e.g., glass coating thereon. The heating resistors of the heaters 15 and 17 can be provided by coating a resistive material, preferably, on the substantially whole surfaces of the corresponding inner or outer walls of the ceramic structures.

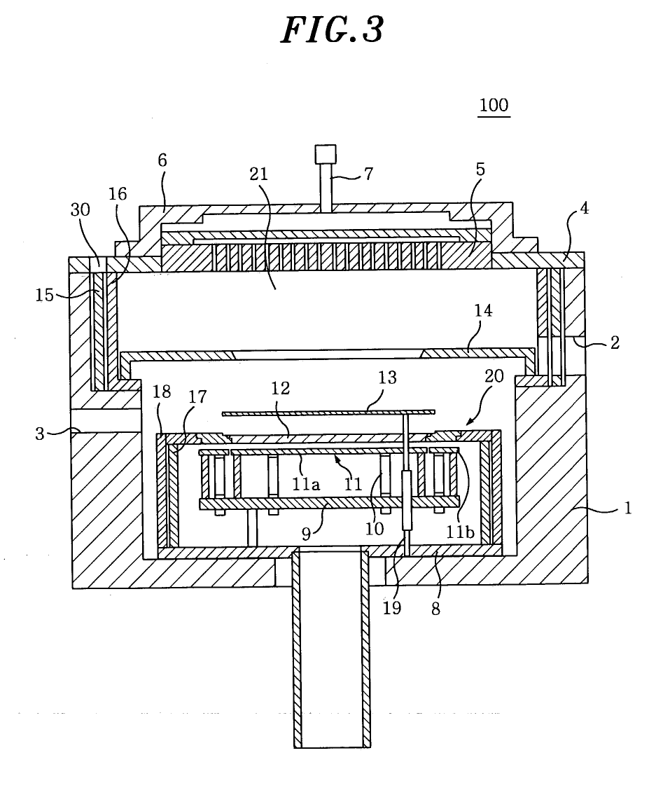

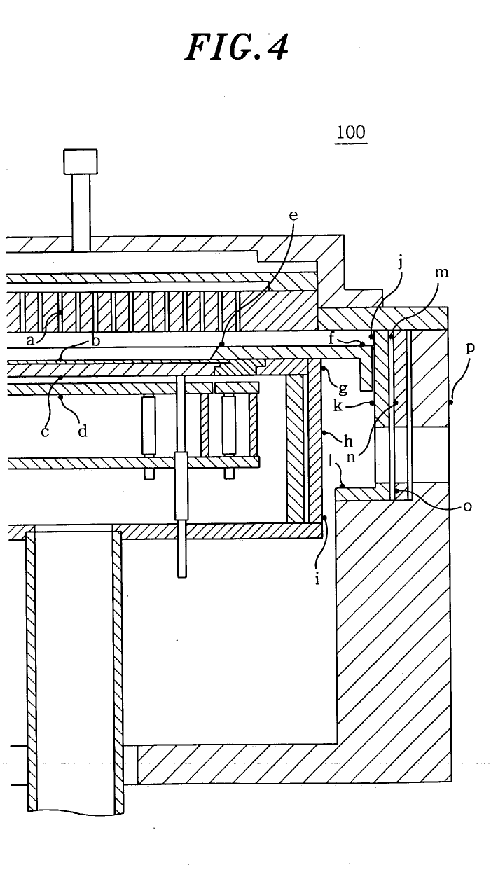

With reference to FIGS. 3 and 4, a method of forming a ruthenium layer on the wafer 13 by using the substrate processing apparatus 100 in FIGS. 1 and 2 will be explained.

In FIG. 3, the heater unit 20 is moved down to a lower position such that the wafer 13 can be transported into the reaction chamber 21 through the transporting port 3 and loaded onto the susceptor 12 of the heater unit 20. After the loading, the heater unit 20 is moved up to an upper position illustrated in FIG. 1, wherein the wafer 13 on the susceptor 12 reaches a top portion of the reaction chamber 21.

The wafer 13 is heated by the plate heater 11 so that the temperature thereof can reach a processing temperature of about 290 to about 35020 C. Nitrogen (N₂) gas is continuously supplied into the reaction chamber 21 during the heating process and, then, oxygen-containing gas and ruthenium-containing material gas that is vaporized Ru(EtCp)₂ are supplied into the space disposed over the shower plate 5 by the gas supply pipe 7. The shower plate 5 makes the material gas and the oxygen-containing gas be dispersed and therefore uniformly supplied on the wafer 13, on which a chemical reaction forms a ruthenium layer. After the ruthenium layer is formed having a desired thickness, the supply of the material gas and the oxygen-containing gas is stopped and nitrogen gas is introduced to purge remaining gas from the reaction chamber 21.

After the chemical vapor deposition is finished, the elevator moves down the heater unit 20 from the upper position to the lower position thereof. Herein, the pin 19 is stopped after contacting a bottom floor of the furnace body 1 while the susceptor 12 is moved down until the supporting structure 8 contacts the bottom floor, whereby the pin 19 is relatively protruded through the susceptor 12 such that the processed wafer 13 can be unloaded from the susceptor 12. After the processed wafer 13 is transported out of the furnace body 1 through the transporting port 3, another wafer will be loaded on the susceptor 12 therethrough and the chemical vapor deposition will be performed again.

It may be preferable to introduce nitrogen gas via a supply port 30, most preferably provided at the farthest part on the supporting plate 4 corresponding to the upper portion of the first cylindrical heater 15 during the supply of the material gas. Then, since the nitrogen gas flows into the reaction chamber 21 through gaps interposed between the furnace body 1, the first cylindrical heater 15, the first cylindrical cover 16, and/or the supporting plate 4 and then is exhausted via the gas exhaust outlet 2, the material gas is prevented from flowing through the gaps and therefore the first cylindrical heater 15 can be isolated or protected therefrom. It should be apparent to those skilled art that other gas, e.g., H₂ or an inert gas such as Ar can be used in lieu of N₂.

In the above-described substrate processing apparatus 100, exposed surfaces of the first and the second cylindrical cover 16 and 18 are heated to a preset temperature, e.g., about 15020 C., by the first and the second cylindrical heater 15 and 17, respectively. At the preset temperature of about 15020 C., the material gas is neither condensed nor deposited on the surface of the first and the second cylindrical cover 16 and 18. Accordingly, contamination of the reaction chamber 21 or wasteful use of the costly Ru(EtCp)₂ can be avoided; and emissivity is rarely changed on the inner wall of the reaction chamber 21 so that the thermal condition in the reaction chamber 21 can be maintained same without deteriorating the CVD condition therein.

In addition, the first and the second cylindrical heater 15 and 17 can be easily repaired or replaced when needed. It is because the first cylindrical heater 15 is detachably mounted at the concave inner wall portion, i.e., on the inwardly protruded inner wall portion of the furnace body 1 and the second cylindrical heater 17 is detachably joined with the feeder part 24. Further, the first cylindrical cover 16 is provided along the inner side of the first cylindrical heater 15 installed along the inner surface of the reaction chamber 21 and the second cylindrical cover 16 is provided along the outer periphery of the second cylindrical heater 17 of the heater unit 20. Therefore, the inner side of the reaction chamber 21 can be protected from formation of the ruthenium layer by the first and the second cylindrical cover 16 and 18, obviating the cleaning process of the Ru layer which would otherewise be formed on the inner wall of the reaction chamber 21. In case the ruthenium layer is formed on the surfaces of the cylindrical cover 16 or 18 facing the reaction chamber 21 and cannot be removed by a routine cleaning process, the cylindrical cover can be replaced with a new one without affecting a corresponding cylindrical heater.

In such a case, the first and the second cylindrical cover 16 and 18 can be readily assembled with or dissembled from the furnace body 1 and the heater unit 20, respectively, because the first cylindrical cover 16 is mounted on the inwardly protruded wall portion of the furnace body 1 and the second cylindrical cover 18 is installed on the supporting structure 8. Resultantly, maintenance cost for the substrate processing apparatus 100 in accordance with the preferred embodiment of the present invention can be reduced.

Further, because the first and the second cylindrical cover 16 and 18 cover the first and the second cylindrical heater 15 and 17 and are directly heated by the corresponding heaters, the temperature thereof can be easily controlled by the heaters 15 and 17; and, therefore, condensation of the material gas and formation of the ruthenium layer are surely avoided on the surface of each cylindrical cover exposed to the material gas in the reaction chamber 21. Furthermore, because the cylindrical cover is made of ceramic substance instead of metal, metallic contamination can be prevented in the reaction chamber 21.

In an experiment of the inventors, when the temperature of the wafer 13 in FIG. 1 was set to about 300° C. without operating the first and the second cylindrical heater 15 and 17, temperatures of a first to a sixteenth point “a” to “p” in FIG. 4 were measured as in Table 1.

TABLE 1

| Point | a | b | c | d | e | f | g | h | i | j | k | l | m | n | o | p |
|---|---|---|---|---|---|---|---|---|---|---|---|---|---|---|---|---|
| T (° C.) | 172 | 296 | 320 | 340 | 245 | 171 | 156 | 152 | 149 | 123 | 117 | 106 | 98 | 98 | 98 | 71 |

On the other hand, under the operation of the first and the second cylindrical heater 15 and 17 at the preset temperature of about 150° C., temperatures of the first to the sixteenth point “a” to “p” were measured as in Table 2.

TABLE 2

| Point | a | b | c | d | e | f | g | h | i | j | k | l | m | n | o | p |
|---|---|---|---|---|---|---|---|---|---|---|---|---|---|---|---|---|
| T (° C.) | 172 | 296 | 320 | 340 | 250 | 185 | 173 | 169 | 165 | 158 | 154 | 137 | 150 | 150 | 149 | 93 |

As clearly shown from the experimental data, temperatures of the exposed surfaces at points “j” to “l” of the cylindrical cover 16 were close to 150° C. (158, 154, and 137° C., respectively) when the cylindrical heaters 15 and 17 are turned on. However, without operating the cylindrical heaters 15 and 17, temperatures of the exposed surfaces at points “j” to “l” of the cylindrical cover 16 are much lower than 150° C. (123, 117, and 106° C., respectively) as shown in Table 1.

Though the preferred embodiment of the present invention refers to the substrate processing apparatus that can perform the MOCVD process, the present invention may be adapted for a different substrate processing apparatus. Further, instead of the vaporized Ru(EtCp)₂, a different vaporized metal-organic compound may be employed as the material gas of the preferred embodiment.

While the invention has been shown and described with respect to the preferred embodiments, it will be understood to those skilled in the art that various changes and modifications may be made without departing from the spirit and scope of the invention as defined in the following claims.

What is claimed is:

1. A substrate processing apparatus for processing a substrate, comprising:
a reaction chamber including a sidewall;
a protection cover facing an inner surface of the sidewall of the reaction chamber;
a first heater, interposed between the sidewall of the reaction chamber and the protection cover, for heating the protection cover;
a second heater positioned in the reaction chamber for heating the substrate; and
a gas supplying member communicating with the reaction chamber for supplying a material gas on the substrate.

2. The apparatus of claim 1, wherein the material gas includes vaporized Ru(EtCp)₂.

3. The apparatus of claim 2, wherein a ruthenium layer is formed on the substrate by using the apparatus.

4. The apparatus of claim 1, wherein the protection cover is heated at about 150° C.

5. The apparatus of claim 1, wherein the substrate is a semiconductor wafer.

6. The apparatus of claim 1, wherein the protection cover is detachably assembled with the sidewall of the reaction chamber.

7. The apparatus of claim 1, wherein the first heater is detachably installed on the sidewall of the reaction chamber.

8. The apparatus of claim 1, wherein the protection cover is made of ceramic substance.

9. The apparatus of claim 8, wherein the ceramic substrate is selected from quartz and alumina.

10. The apparatus of claim 1, further comprising a third heater provided around a periphery of the second heater and a protective cover covering the third heater at the outside thereof, the protective cover being heated by the third cover.

11. The apparatus of claim 10, wherein the first and the third heater generally have a cylindrical shape, the first heater having a resistive material coated on an inner surface of a sidewall thereof and the third heater being provided with a resistive material formed on an outer surface of a sidewall thereof.

12. The apparatus of claim 10, wherein the protective cover faces the protection cover.

13. The apparatus of claim 1, wherein the gas supplying member includes a gas supply pipe and a shower plate for uniformly supplying the material gas on the substrate.

14. The apparatus of claim 1, further comprising a member which flows an additional gas via a gap between the protection cover and the first heater and that between the reaction chamber and the first heater in order to isolate the first heater from the material gas.

15. The apparatus of claim 14, further comprising a gas exhaust outlet provided at a part of the reaction chamber and the member for flowing the additional gas is provided at a farthest part of the reaction chamber from the gas exhaust outlet.

16. The apparatus of claim 14, wherein the additional gas is nitrogen.

17. A method for processing a substrate using a substrate processing apparatus, which includes a) a reaction chamber having a sidewall, b) a protection cover facing an inner surface of the sidewall of the reaction chamber, c) a first heater, interposed between the sidewall of the reaction chamber and the protection cover, for heating the protection cover, d) a second heater positioned in the reaction chamber for heating the substrate, and e) a gas supplying member communicating with the reaction chamber for supplying a material gas on the substrate, the method comprising the steps of:
loading the substrate into the reaction chamber;
heating the substrate by using the second heater while the protection cover is heated by using the first heater;
supplying the material gas on the substrate by using the gas supplying member to thereby make the substrate processed; and
unloading the processed substrate out of the reaction chamber.

18. A chemical vapor deposition apparatus for processing a substrate, comprising:
a reaction chamber having a sidewall;
a heater installed on an inner surface of the sidewall of the reaction chamber; and
a protection cover assembled with the sidewall of the reaction chamber to cover the heater.
